(19) United States
(12) Patent Application Publication
(10) Pub. No.: US 2016/0095249 A1
(43) Pub. Date: Mar. 31, 2016

(54) PRINTED CIRCUIT BOARD AND ELECTRONIC COMPONENT PACKAGE HAVING THE SAME

(71) Applicant: SAMSUNG ELECTRO-MECHANICS CO., LTD., Suwon-si (KR)

(72) Inventor: Hyoung KIM, Suwon (KR)

(73) Assignee: SAMSUNG ELECTRO-MECHANICS CO., LTD., Suwon-si (KR)

(21) Appl. No.: 14/672,770

(22) Filed: Mar. 30, 2015

(30) Foreign Application Priority Data
Sep. 26, 2014 (KR) 10-2014-0129313

(51) Int. Cl. H05K 7/20; H05K 1/02

(52) U.S. Cl. CPC H05K 7/2039; H05K 1/0203

(57) ABSTRACT

Disclosed are a printed circuit board and an electronic component package having the printed circuit board, which includes: a base board; a heat-dissipating pad formed on the based board and having an electronic component installed thereon; and a bridging pad formed on the base board between the heat-dissipating pad and a shield can installed on the base board so as to allow heat generated by the electronic component to be transferred from the heat-dissipating pad to the shield can.

### CROSS-REFERENCE TO RELATED APPLICATIONS

This application claims the benefit of Korean Patent Application No. 10-2014-0129313, filed with the Korean Intellectual Property Office on Sep. 26, 2014, the disclosure of which is incorporated herein by reference in its entirety.

### BACKGROUND

1. Technical Field

The present invention relates to a printed circuit board and an electronic component package having the same.

2. Background Art

The integrated circuit technology has been continuously improving, and accordingly the chips have become increasingly smaller. Moreover, various electronic devices have been designed in smaller sizes.

Chips are a heat source and thus generate heat during the operation. There has been an increasing quantity of chips installed in the substrate, resulting in an increase of heat density. Accordingly, without a proper heat dissipation, the heat may adversely affect the chips and cause a malfunction of the chips.

While vias or the like may be used for dissipating the heat generated by the chips, this may cause an unnecessary discharge of solders through the vias. Moreover, dissipating the heat through the vias is not very efficient.

The related art of the present invention is disclosed in Korean Patent Publication No. 10-2014-0078547 (laid open on Jun. 25, 2014; CHIP THERMAL DISSIPATION STRUCTURE).

### SUMMARY

The present invention provides a printed circuit board and an electronic component package that may discharge heat generated by the electronic component to a shield can.

An aspect of the present invention provides an electronic component package that may discharge heat generated by an electronic component to a shield can, by forming a bridging pad between a heat-dissipating pad and the shield can.

The electronic component package may include: a base board; a heat-dissipating pad formed on the base board; an electronic component installed on the heat-dissipating pad; a shield can installed on the base board so as to cover the electronic component; and a bridging pad formed on the base board between the heat-dissipating pad and the shield can so as to allow heat generated by the electronic component to be transferred from the heat-dissipating pad to the shield can.

One end of the bridging pad may be in contact with the heat-dissipating pad, and the other end thereof may be in contact with an inside surface of the shield can.

The bridging pad may be formed as a straight line from the heat-dissipating pad toward the shield can.

The electronic component package may further include a solder resist formed on the base board in such a way that at least a portion of the bridging pad is exposed.

The electronic component may be installed on the bridging pad. Moreover, a solder for allowing the electronic component to be installed may be formed at the exposed portion of the bridging pad.

The solder resist may cover a portion of the bridging pad that is adjacent to the shield can, and the solder resist may cover a portion of the bridging pad that is adjacent to the heat-dissipating pad.

The electronic component package may further include a connection pad formed around the heat-dissipating pad on the base board so as to be connected with the electronic component.

The bridging pad may be grounded to the shield can.

Another aspect of the present invention provides a printed circuit board having a bridging pad formed between a heat-dissipating pad and a shield can so as to allow heat generated by an electronic component to be discharged to the shield can.

The printed circuit board may include: a base board; a heat-dissipating pad formed on the based board and having an electronic component installed thereon; and a bridging pad formed on the base board between the heat-dissipating pad and a shield can installed on the base board so as to allow heat generated by the electronic component to be transferred from the heat-dissipating pad to the shield can.

### BRIEF DESCRIPTION OF DRAWINGS

FIG. 1 shows an electronic component package in accordance with an embodiment of the present invention.

FIG. 2 shows an inside of the electronic component package in accordance with an embodiment of the present invention.

FIG. 3 shows a printed circuit board in accordance with an embodiment of the present invention.

FIG. 4 shows the printed circuit board and a pad in accordance with an embodiment of the present invention.

### DETAILED DESCRIPTION

Hereinafter, a printed circuit board and an electronic component package having the same in accordance with the present invention will be described with reference to the accompanying drawings. In describing the present invention with reference to the accompanying drawings, any identical or corresponding elements will be assigned with same reference numerals, and their description will not be provided redundantly.

Terms such as “first” and “second” may be used in describing various elements, but the above elements shall not be restricted to the above terms. The above terms are used only to distinguish one element from the other.

When one element is described to be “coupled” to another element, it does not refer to a physical, direct contact between these elements only, but it shall also include the possibility of yet another element being interposed between these elements and each of these elements being in contact with said yet another element.

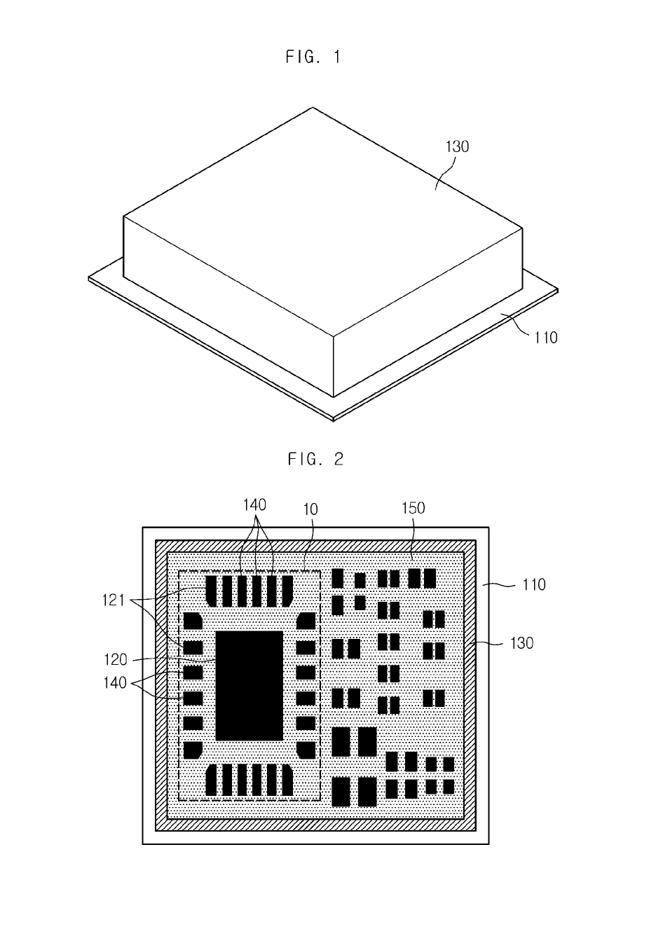

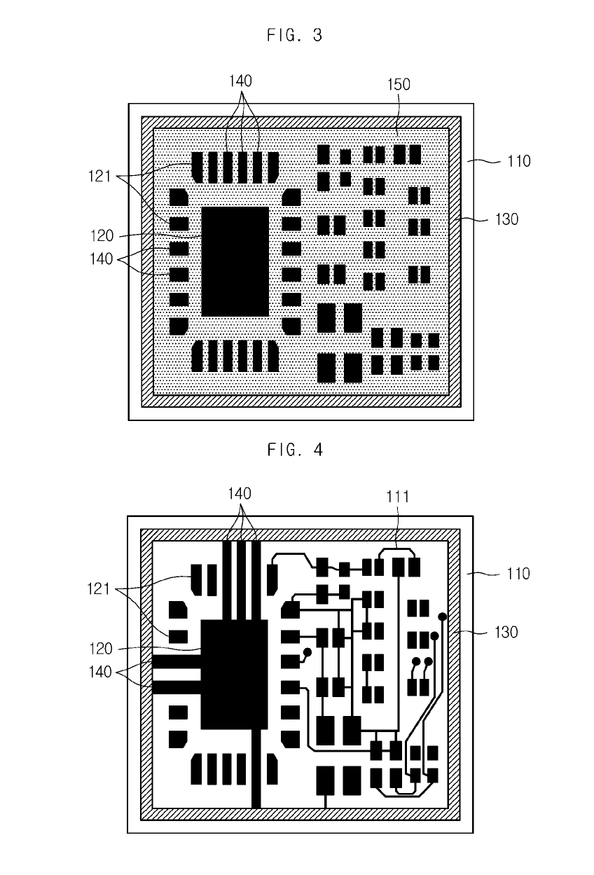

FIG. 1 shows an electronic component package in accordance with an embodiment of the present invention. FIG. 2 shows an inside of the electronic component package in accordance with an embodiment of the present invention. FIG. 3 shows a printed circuit board in accordance with an embodiment of the present invention. FIG. 4 shows the printed circuit board and a pad in accordance with an embodiment of the present invention.

Referring to FIG. 1 to FIG. 4, the printed circuit board in accordance with an embodiment of the present invention may include a base board 110, a heat-dissipating pad 120, a connection pad 121, a bridging pad 140 and a solder resist 150.

Moreover, the electronic component package in accordance with an embodiment of the present invention may include an electronic component 10, the base board 110, the heat-dissipating pad 120, the connection pad 121, a shield can 130, the bridging pad 140 and the solder resist 150.

The electronic component 10 may include components such as an active device and a passive device and may be, for example, an integrated circuit chip. Heat is generated from the electronic component 10 when the electronic component 10 operates.

The base board 110 is a board including an insulation layer and a circuit 111. Here, the insulation layer may be an insulation material such as prepreg and may have glass fiber inserted therein, as necessary, for enhancement of rigidity. The circuit 111 is wiring formed on one surface or both surfaces of the insulation layer and may be formed with a metal such as copper.

The heat-dissipating pad 120 is formed on the base board 110 and functions to dissipate the heat generated by the electronic component 10. The heat-dissipating pad 120 is formed in an area for installing the electronic component 10. Specifically, the electronic component 10 is installed on one surface of the heat-dissipating pad 120. The heat-dissipating pad 120 may have a greater area than other pads in order to increase a heat-dissipating efficiency of the electronic component 10.

The connection pad 121 is electrically connected with the circuit 111 and has a chip connected thereto. The connection pad 121 may be arranged around the heat-dissipating pad 120 and formed beneath an area for installing the chip.

The shield can 130 covers the electronic component 10 to shield electromagnetic waves. As shown in FIG. 1, the shield can 130 may have a cuboidal shape and may have a receiving space therein. Received in the receiving space of the shield can 130 is the electronic component 10. The shield can 130 may be made of a conductive material such as a metal.

The bridging pad 140 is formed between the heat-dissipating pad 130 and the shield can 130 on the base board 110 so that the heat generated by the electronic component 10 may be transferred from the heat-dissipating pad 120 to the shield can 130.

At least a portion of the bridging pad 140 may be covered by the electronic component 10. That is, the electronic component 10 may be installed on the bridging pad 140.

The bridging pad 140 may be formed to be extended from the heat-dissipating pad 120 toward the shield can 130 and may be provided in plurality around the heat-dissipating pad 120. In other words, the bridging pad 140 may be formed radially about the heat-dissipating pad 120.

One end of the bridging pad 140 may be in contact with the heat-dissipating pad 120, and the other end thereof may be in contact with an inside surface of the shield can 130. In such a case, the bridging pad 140 may be formed with a shortest distance from the heat-dissipating pad 120 to the shield can 130. In other words, the bridging pad 140 may be formed as a straight line from the heat-dissipating pad 120 toward the shield can 130. Accordingly, the heat may be transferred quickly from the heat-dissipating pad 120 to the shield can 130.

The bridging pad 140 may be grounded to the shield can 130. That is, the bridging pad 140 may simultaneously discharge static electricity generated inside the electronic component 10 while dissipating the heat from the electronic component 10.

The connection pad 121 may be extended in parallel with the bridging pad 140. In such a case, the connection pad 121 may be shorter than the bridging pad 140 and may be formed to be separated from the heat-dissipating pad 120 and the shield can 130.

The circuit 111, the connection pad 121 and the bridging pad 140 may be all formed simultaneously. For example, the circuit 111, the connection pad 121 and the bridging pad 140 may be formed simultaneously through a photolithography process.

The solder resist 150 covers the circuit 111 in order to protect the circuit 111. The solder resist 150 does not cover the heat-dissipating pad 120. In other words, the heat-dissipating pad 120 is exposed. Moreover, the solder resist 150 exposes at least a portion of the bridging pad 140. Formed where the heat-dissipating pad 120 and the bridging pad 140 are exposed is a solder, by which the chip may be installed.

That is, the solder resist 150 covers portions of the bridging pad 140 other than a portion where the solder is formed, and this is to prevent the solder from being formed at unnecessary portions other than the area for installing the electronic component 10.

In such a case, a portion of the bridging pad 140 that is adjacent to the shield can 130 may be covered by the solder resist 150. That is, as illustrated in FIG. 2 and FIG. 3, in the electronic component package formed with the solder resist 150, the bridging pad 140 appears visually as if a middle portion thereof is disconnected from the shield can 130 by the solder resist 150.

Moreover, a portion of the bridging pad 140 that is adjacent to the heat-dissipating pad 120 may be covered by the solder resist 150. Likewise, the bridging pad 140 appears visually as if a middle portion thereof is disconnected from the heat-dissipating pad 120 by the solder resist 150.

As described above, with the printed circuit board and the electronic component package including the printed circuit board in accordance with an embodiment of the present invention, the heat generated by the electronic component may be transferred to the shield can by the bridging pad, thereby enabling an efficient dissipation of the heat.

Although a certain embodiment of the present invention has been described above, it shall be appreciated that there can be a variety of permutations and modifications of the present invention by those who are ordinarily skilled in the art to which the present invention pertains without departing from the technical ideas and scope of the present invention, which shall be defined by the appended claims. It shall be also appreciated that a large number of other embodiments than the above-described embodiment are included in the claims of the present invention.

What is claimed is:

1. An electronic component package comprising:
a base board;
a heat-dissipating pad formed on the base board;
an electronic component installed on the heat-dissipating pad;
a shield can installed on the base board so as to cover the electronic component; and
a bridging pad formed on the base board between the heat-dissipating pad and the shield can so as to allow heat generated by the electronic component to be transferred from the heat-dissipating pad to the shield can.

2. The electronic component package of claim 1, wherein one end of the bridging pad is in contact with the heat-dissipating pad and the other end thereof is in contact with an inside surface of the shield can.

3. The electronic component package of claim 2, wherein the bridging pad is formed as a straight line from the heat-dissipating pad toward the shield can.

4. The electronic component package of claim 1, further comprising a solder resist formed on the base board in such a way that at least a portion of the bridging pad is exposed.

5. The electronic component package of claim 4, wherein the electronic component is installed on the bridging pad.

6. The electronic component package of claim 5, wherein a solder for allowing the electronic component to be installed is formed at the exposed portion of the bridging pad.

7. The electronic component package of claim 6, wherein the solder resist covers a portion of the bridging pad that is adjacent to the shield can.

8. The electronic component package of claim 6, wherein the solder resist covers a portion of the bridging pad that is adjacent to the heat-dissipating pad.

9. The electronic component package of claim 1, further comprising a connection pad formed around the heat-dissipating pad on the base board so as to be connected with the electronic component.

10. The electronic component package of claim 1, wherein the bridging pad is grounded to the shield can.

11. A printed circuit board comprising:
a base board;
a heat-dissipating pad formed on the based board and having an electronic component installed thereon; and
a bridging pad formed on the base board between the heat-dissipating pad and a shield can installed on the base board so as to allow heat generated by the electronic component to be transferred from the heat-dissipating pad to the shield can.

12. The printed circuit board of claim 11, wherein one end of the bridging pad is in contact with the heat-dissipating pad and the other end thereof is extended toward the shield can.

13. The printed circuit board of claim 12, wherein the bridging pad is formed as a straight line.

14. The printed circuit board of claim 11, further comprising a solder resist formed on the base board in such a way that at least a portion of the bridging pad is exposed.

15. The printed circuit board of claim 14, wherein the solder resist covers a portion of the bridging pad that is adjacent to the shield can.

16. The printed circuit board of claim 14, wherein the solder resist covers a portion of the bridging pad that is adjacent to the heat-dissipating pad.

17. The printed circuit board of claim 11, further comprising a connection pad formed around the heat-dissipating pad on the base board so as to be connected with the electronic component.
